(19) United States
(12) Patent Application Publication
(10) Pub. No.: US 2026/0112573 A1
(43) Pub. Date: Apr. 23, 2026

(54) METHOD AND APPARATUS FOR CHARGE COMPENSATION DURING 3D TOMOGRAPHY

(71) Applicant: Carl Zeiss SMT GmbH, Oberkochen (DE)

(72) Inventors: Thomas KORB, Schwaebisch Gmuend (DE); Hyun Hwa KIM, Huettlingen (DE); Eugen FOCA, Ellwangen (DE); Andrew John MURRAY, Gatineau (CA)

(21) Appl. No.: 19/429,021

(22) Filed: Dec. 22, 2025

Related U.S. Application Data
(63) Continuation of application No. PCT/EP2024/066083, filed on Jun. 11, 2024.

(30) Foreign Application Priority Data
Jun. 27, 2023 (DE) 10 2023 206 064.7

(51) Int. Cl. H01J 37/305; H01J 37/28; H01J 37/30; H01J 37/304

(52) U.S. Cl. CPC H01J 37/3056; H01J 37/28; H01J 37/3005; H01J 37/304; H01J 2237/30472; H01J 2237/31745

(57) ABSTRACT

A method comprises, during ion-beam milling of a cross-section surface into a wafer with an ion beam, compensating a milling-induced charging by scanning a charged particle imaging beam over a segment of the cross-section surface. The method further comprises adjusting a kinetic energy of the charged particle imaging beam to reduce a surface charge generated during ion-beam milling.

### CROSS-REFERENCE TO RELATED APPLICATIONS

The present application is a continuation of, and claims benefit under 35 USC 120 to, international application No. PCT/EP2024/066083, filed Jun. 11, 2024, which claims benefit under 35 USC 119 of German Application No. 10 2023 206 064.7, filed Jun. 27, 2023. The entire disclosure of each of these applications is incorporated by reference herein.

### FIELD

The present disclosure relates to a pattern measurement method of semiconductor objects within a semiconductor wafer. The present disclosure relates to a method, a computer program product and a corresponding semiconductor inspection device for performing 3D tomography at a wafer. With the semiconductor inspection device and the method of the disclosure, it is possible for a charging effect during imaging to be mitigated and for a relatively high precision of the image formation to be maintained. The method, computer program product and semiconductor inspection device can be utilized for various inspection tasks, such as quantitative metrology, defect detection, process monitoring, or defect review of integrated circuits within semiconductor wafers.

### BACKGROUND

Semiconductor structures are amongst the finest man-made structures. Semiconductor manufacturing involves relatively precise manipulation, e.g., lithography or etching, of materials such as silicon or oxide at very fine scales in the range of nm. A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patters can be subject to several influences. For example, during the manufacturing of 3D-memory devices, the processes currently include etching and deposition. Other process steps such as the lithography exposure or implantation also can have an impact on the properties of the elements of the integrated circuits. Fabricated semiconductor structures can suffer from rare and different imperfections. Devices for quantitative metrology, defect-detection or defect review look for these imperfections. These devices are not only used during wafer fabrication. As this fabrication process is relatively complicated and relatively non-linear, optimization of production process parameters can be difficult. As a remedy, an iteration scheme called process window qualification (PWQ) can be applied. In each iteration a test wafer is manufactured based on the currently best process parameters, with different dies of the wafer being exposed to different manufacturing conditions. By detecting and analyzing the test structures with devices for quantitative metrology and defect-detection, the best manufacturing process parameters can be selected. In this way, production process parameters can be tweaked towards optimality. Afterwards, a relatively accurate quality control process and device for the metrology semiconductor structures in wafers can be used.

Fabricated semiconductor structures are typically prepared based on known processes. The semiconductor structures are manufactured in a sequence of layers being parallel to a surface of a substrate. For example, in a logic type sample, metal lines run parallel in metal layers or HAR (high aspect ratio) structures and metal vias run perpendicular to the metal layers. The angle between metal lines in different layers is either 0° or 90°. On the other hand, for VNAND type structures their cross-sections are circular on average. Furthermore, a semiconductor wafer typically has a diameter of 300 mm and comprises a plurality of several sites, so called dies, each comprising at least one integrated circuit pattern such as for example for a memory chip or for a processor chip. During fabrication, semiconductor wafers can run through about 1,000 process steps, and within the semiconductor wafer, about 100 and more parallel layers are formed, comprising the transistor layers, the layers of the middle of the line, and the interconnect layers and, in memory devices, a plurality of 3D arrays of memory cells.

In general, the aspect ratio and the number of layers of integrated circuits is constantly increasing and the structures are growing into third (vertical) dimension. The current height of the memory stacks exceeds a dozen of micrometers. In contrast, the minimum features size are generally becoming smaller. The minimum feature size or critical dimension is below 10 nm, for example 7 nm or 5 nm, and is expected approach feature sizes about and below 3 nm in near future. While the complexity and dimensions of the semiconductor structures are generally growing into the third dimension, the lateral dimensions of integrated semiconductor structures are becoming smaller. Therefore, measuring the shape, dimensions and orientation of the features and patterns in three dimensions (3D) and their overlay with relatively high precision can become challenging. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can generally be reduced with no physical limitation. The charged particle beam diameter generally has a limited dimension, which generally depends on the charged particle beam operation conditions and lens. The beam resolution is generally limited by approximately half of the beam diameter. The lateral resolution can be below 2 nm, for example even below 1 nm.

A common way to generate 3D tomographic data from semiconductor samples on nm scale is the so-called slice and image approach obtained for example by a dual beam device. A slice-and image approach is described in WO 2020/244795 A1. According to the method of the WO 2020/244795 A1, a 3D volume inspection is obtained at an inspection sample extracted from a semiconductor wafer. In another example, the slice and image method is applied under a slanted angle into the surface of a semiconductor wafer, as described in WO 2021/180600 A1. According to this method, a 3D volume image of an inspection volume is obtained by slicing and imaging a plurality of cross-section surfaces within the inspection volume. For a relatively precise measurement, a large number N of cross-section surfaces in the inspection volume is generated, with the number N exceeding 100 or even more image slices. For example, in a volume with a lateral dimension of 5 μm and a slicing distance of 5 nm, 1,000 slices are milled and imaged. With an exemplary sample of a plurality of HAR structures with a pitch of for example 70 nm, about 5,000 HAR structures are in one field of view, and a total sum of more than five million cross sections of HAR structures is generated. One exemplary task of semiconductor inspection is to determine a set of specific parameters of semiconductor objects such as high aspect ratio (HAR)—structures inside the inspection volume. Such parameters are for example a dimension, area, a shape, or other measurement parameters.

Generally, semiconductors comprise many repetitive three-dimensional structures. During the manufacturing process or a process development, some selected physical or geometrical parameters of a representative plurality of the three-dimensional structures are measured with relatively high accuracy and high throughput. For monitoring the manufacturing, an inspection volume is defined which comprises the representative plurality the three-dimensional structures. This inspection volume is then analyzed for example by a slice and image approach, which can lead to a 3D volume image of the inspection volume with relatively high resolution. From the large number of image slices, a three-dimensional volume image is derived with high accuracy. However, even relatively small charging effects at the wafer or cross section surfaces can cause for example image distortion, which can deteriorate the derivation of a three-dimensional volume image and can decrease the accuracy of the final inspection or measurement task.

Even relatively small charging effects at the wafer or cross section surfaces can cause changes of a local image contrast and can cause a wrong determination of edges of features and thus the edge detection algorithms used for CD measurements.

### SUMMARY

The disclosure seeks to provide a relatively efficient method of charge mitigation during imaging a plurality of cross section surfaces generated into a wafer. The disclosure seeks to provide an inspection apparatus configured to execute a method of charge mitigation.

In a first embodiment, a method of ion-beam milling a cross-section surface into a wafer with reduced impact of a charging effect is provided. The method comprises, during performing the ion-beam milling of the cross-section surface, compensating a milling-induced charging by scanning a second charged particle imaging beam over at least a segment of the cross-section surface during ion-beam milling. The method of ion-beam milling can be performed with an ion beam comprising an ion species, which can for example be selected from a group of ion species including Gallium ions, Xenon ions, Oxygen ions, Neon ions, Argon ions, and Helium ions.

In an example, the method further comprises adjusting a kinetic energy of the second charged particle imaging beam to reduce a surface charge generated during ion-beam milling. With the kinetic energy, a secondary electron yield and a charging behavior of a wafer surface can be adjusted. In an example, the kinetic energy is adjusted below a minimum low-energy transition energy or above a maximum high energy transition energy of material compositions present at an inspection site of the wafer. With transition energy, the kinetic energy of a charged particle beam is meant at which—for a specific material composition—no secondary electrons are generated. During ion-beam milling, for example a positive surface charge is generated. With kinetic energies below the low-energy transition energy or above the high energy transition energy, negative surface charging is generated by the second charged particle imaging beam, and thereby, a positive charging due to ion beam milling can be compensated.

In an example, the method further comprises generating a temporally conducting zone between the cross-section surface and a capacity by scanning the second charged particle imaging beam between the cross section-surface and the capacity to enable a flow of charges from the cross-section surface to the capacity. Thereby, a charging due to ion beam milling can be drained to the capacity and effects of surface charging are avoided or compensated. Generating the temporally conducting zone can be performed during the ion-beam milling. Prior to generating a temporally conducting zone between the cross-section surface and the capacity, the kinetic energy of the charged particle imaging beam can be adjusted.

In an example the method further comprises at least one step of image forming by scanning the second charged particle imaging beam over the cross-section surface of the wafer to form a two-dimensional image of the cross-section surface. The method can comprise several repetitions of the steps of image forming, ion-beam milling and compensating a milling-induced charging to acquire a plurality of two-dimensional images of a plurality of cross-section surfaces with reduced impact of a charging during ion-beam milling or image forming.

According to a second embodiment, a method of image acquisition comprises at least one step of image forming to form a two-dimensional image of a segment of a surface of a wafer, for example a cross-section surface generated by ion-beam milling. The step of image forming is achieved by scanning a charged particle imaging beam over the segment of the surface. The charged particle imaging beam is for example an electron beam or an ion beam, for example a Helium ion beam. The method of image acquisition further comprises a step of generating a temporally conducting zone between the segment of the surface and a capacity. The temporally conducting zone is generated by scanning the charged particle imaging beam between the segment of the surface and the capacity. Thereby, a flow of charges can be enabled and charged flow from the segment of the surface to the capacity. Thereby, a local surface charging of the segment of the surface, induced by scanning the charged particle imaging beam over the segment, is reduced, and charging effects can be mitigated.

In an example, the method of image acquisition further comprises at least one step of ion-beam milling of the segment of the surface of a wafer with an ion beam. Thereby, a cross-section surface can be formed as a segment of the surface. In an example, an optical axis of the ion beam is arranged at an angle GFE between 30° and 60° to the optical axis of the charged particle imaging beam. Thereby, a cross-section can be formed at a slanted angle into the wafer. In an example, the step of generating a temporally conducting zone by scanning the charged particle imaging beam is performed during the ion-beam milling-step. The step of generating a temporally conducting zone can be performed during image forming and ion-beam milling. In an example, a kinetic energy of the charged particle imaging beam is adjusted prior to generating a temporally conducting zone. Thereby, a secondary electron yield and a penetration depth of the charged particle can be adjusted and a conductivity of the temporally conducting zone is increased. In an example, the step of generating a temporally conducting zone is repeated several times during image forming as well as during ion-beam milling, and surface charging during image forming or ion-beam milling can flow to the capacity. Thereby, surface charges can be mitigated during image forming and ion-beam milling.

In an example, the method further comprises a step of compensating a milling-induced charging during ion-beam milling by scanning the charged particle imaging beam over a segment of the cross-section surface during ion-beam milling, for example in parallel to the ion-beam milling process. In an example, prior to compensating the milling-induced charging by scanning the charged particle imaging beam, the method comprises adjusting a kinetic energy of the charged particle imaging beam. Thereby, a secondary electron yield during charged particle beam scanning can be adjusted to and configured to reduce the milling-induced charging.

In an example, the steps of image forming, ion-beam milling and generating a temporally conducting zone are repeated to acquire a plurality of two-dimensional images of a plurality of cross-section surfaces with reduced impact of a charging during ion-beam milling or image forming. Thereby, a plurality of two-dimensional images can be acquired and a three-dimensional volume image of a inspection volume of wafer at an inspection site can be generated.

In an example, several different temporary conducting zones are generated to the same or different capacities.

In an example, the method further comprises the step of determining the capacity adjacent to the segment of the surface of the wafer. The step of determining the capacity can comprise forming the capacity adjacent to the segment of the surface by deposition of a metal volume onto the surface of the wafer. In another example, a large capacity such as a conducting power or ground line is available in the chip design adjacent to an inspection site, which can be used as the capacity for draining surface charges via the temporary conducting zone.

In an example, the method comprises further a step of physically connecting a probe with the capacity to remove accumulated charges from the capacity. The probe can be a needle of pipe capable of conducting charges, which can be moved and positioned with a relatively high-precision actuator. Such probes are known.

In an example, the method further comprises the step of arranging a purge head at the inspection site above the surface of the wafer and the step of providing via a gas supply a purging gas to the purge head to form a local gas purging volume between the dual beam device and the surface of the wafer. The purging gas can be selected and provided for neutralizing surface charges generated during image formation or ion-beam milling. Suitable purging gases include for example selected from a group of gases including Hydrogen, Nitrogen, Xenon, Argon, Neon or Helium.

In an example, the method further comprises an image processing of the at least one two-dimensional image, comprising image processing operations selected from the group of operations including image registration, depth map determination, distortion compensation, magnification adjustment, noise removal, contrast enhancement, image normalization, and thresholding, three-dimensional volume image generation, feature detection, feature extraction, template matching or machine learning object detectors.

In an example, the method further comprises adjusting a first inspection site of a wafer at the optical axis of the charged particle imaging system.

In a third embodiment, a method of operating a dual beam device is provided. The method can reduce charging effects. The method comprises arranging a gas purging head at an inspection site adjacent to a surface of a wafer and providing via a gas supply a purging gas to the gas purging head to form a local gas purging volume. The method further comprises guiding a charged particle imaging beam of the dual beam device through a first beam passing opening of the gas purging head, and guiding an ion-beam of the dual beam device through a second beam passing opening of the gas purging head. With the arrangement a gas purging head with first and second beam passing opening, a confined local gas purging volume can be implemented, and a purging gas can be provided in a confined area above the wafer surface at the inspection side. The method further comprises at least one step of ion-beam milling of at least one cross-section surface at the inspection site into the surface of the wafer with the ion beam, and at least one step of image forming of at least one two-dimensional image of the at least one cross-section surface by scanning the charged particle imaging beam over the at least one cross-section surface. The method further comprises selecting and providing the purging gas configured for neutralizing surface charges generated during ion-beam milling or charged particle image forming. Suitable purging gases can for example be selected from a group of gases including Hydrogen, Nitrogen, Xenon, Argon, Neon or Helium. In an example, the method further comprises adjusting the inspection site of the wafer at the optical axis of the charged particle imaging system.

In a further embodiment, a dual beam system configured for mitigation of charging effects during ion-beam milling or image forming with a charged particle imaging beam is provided. The dual beam system comprises a charged particle imaging system, an ion beam system, a sample stage with a wafer support table or chuck and a control unit. The control unit comprises a memory. The memory is configured for storing a set of instructions. The control unit comprises a processing engine configured to execute the set of instructions to cause the dual beam system to perform any of the methods according to the first to third embodiments.

In an example, the ion beam system is configured for generating a focused ion beam comprising ions selected from a group including Gallium ions, Xenon ions, Oxygen ions, Neon ions, Argon ions, and Helium ions. In an example, an optical axis of the ion beam system is arranged at an angle GFE to the optical axis of the charged particle imaging beam system, and wherein the angle GFE is between 30° and 80°. In an example, the angle GFE=90°. The dual beam system can be part of a wafer inspection system.

According to an example, a dual beam system further comprises a gas purging head arranged between the charged particle imaging system, the ion beam system, and a surface of a wafer or wafer support table. The gas purging head can comprise a first beam passing opening for guiding a charged particle imaging beam through the gas purging head and a second beam passing opening for guiding an ion beam through the gas purging head. The gas purging head can be connected to a gas supply configured for providing during use a purging gas to the gas purging head to form a local gas purging volume. A purging gas can be selected from a group of gases including Hydrogen, Nitrogen, Xenon, Argon, Neon or Helium. In an example, the first beam passing opening and the second beam passing opening are spatially separated and arranged at an angle corresponding to an angle GFE between the ion beam system and the charged particle imaging system. In an example, the first beam passing opening and the second beam passing opening are at least partially overlapping. The gas purging head can be retractably mounted on an actuated mount.

While the examples and embodiments are described at the examples of semiconductor wafers, it is understood that the disclosure is not limited to semiconductor wafers but can for example also be applied to reticles or masks for semiconductor fabrication.

The disclosure described by examples and embodiments is not limited to the embodiments and examples but can be implemented by those skilled in the art by various combinations of the embodiments and examples or modifications thereof. The present disclosure may be even more fully understood with reference to the drawings.

### BRIEF DESCRIPTION OF THE DRAWINGS

FIG. 1 shows an illustration of a wafer inspection or metrology system for 3D volume inspection with a dual beam device.

FIG. 2 is an illustration of the slice-and image method of a volume inspection in a wafer.

FIG. 3 illustrates an example of a cross section image, obtained by the slice-and image method.

FIGS. 4A-4B illustrate examples of a charging effect during milling and imaging of a sample.

FIG. 5 illustrates a charging effect in dependence from a kinetic landing energy of primary electrons.

FIG. 6 illustrates a first example of a method of charge mitigation.

FIG. 7 illustrates certain details of a method of charge mitigation.

FIG. 8 illustrates a method of charge mitigation.

FIGS. 9A-9B show a result of an inspection.

FIG. 10 shows a wafer inspection system according to an embodiment.

FIGS. 11A-11B illustrate a first example of a third embodiment.

FIGS. 12A-12B illustrate a second example of the third embodiment.

### DETAILED DESCRIPTION

Throughout the figures and the description, same reference numbers are used to describe same features or components. The coordinate system is selected that the wafer surface 55 coincides with the XY-plane.

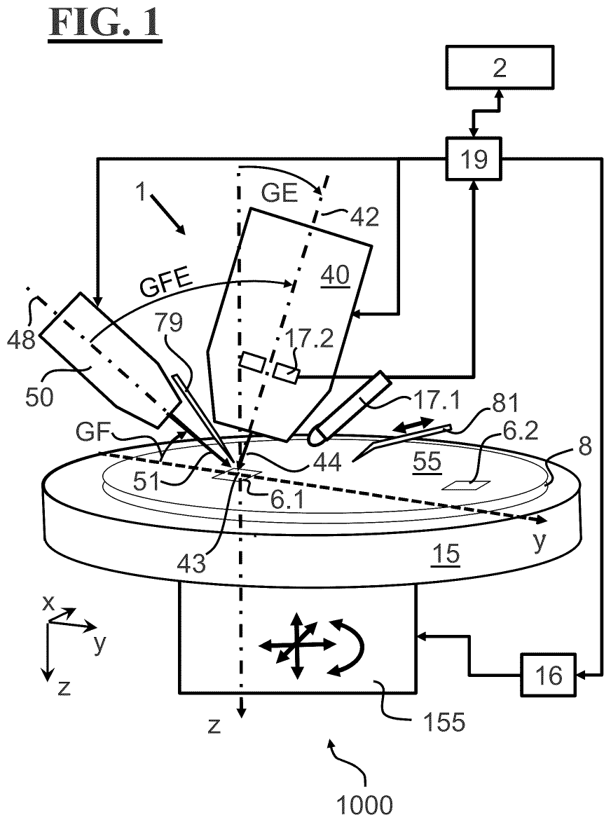

For the investigation of 3D inspection volumes in semiconductor wafers, a slice and imaging method has been proposed, which is applicable to inspection of volumes inside a wafer. In an example, a 3D volume image is generated from an inspection volume inside a wafer by the so called “wedge-cut” approach or wedge-cut geometry, without the need of a removal of a sample piece from the wafer. The slice and image method is applied to an inspection volume with dimensions of few μm, for example with a lateral extension of 5 μm to 10 μm in wafers with diameters of 200 mm or 300 mm. The lateral extension can also be larger and reach up to 30 or 50 micrometers. A V-shaped groove or edge is milled in the top surface of an integrated semiconductor wafer to make accessible a cross-section surface at an angle to the top surface. 3D volume images of inspection volumes are acquired at a limited number of inspection sites, for example representative sites of dies, for example at process control monitors (PCM), or at sites identified by other inspection tools. The slice and image method will destroy the wafer only locally, and other dies may still be used, or the wafer may still be used for further processing. The methods and inspection systems according to the 3D Volume image generation are described in WO 2021/180600 A1, which is fully incorporated herein by reference. An example of a wafer inspection system 1000 for 3D volume inspection is illustrated in FIG. 1. The wafer inspection system 1000 is configured for a slice and imaging method under a wedge cut geometry with a dual beam device 1. For a wafer 8, several inspection sites, comprising inspection sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and mechanisms for precision control for a wafer stage such as Laser interferometers are known. A control unit 16 is configured to control the wafer stage 155 and to adjust an inspection site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. At the intersection point 43 of both optical axes of FIB and CPB imaging system, the wafer surface 55 is arranged at a slant angle GF to the FIB axis 48. FIB axis 48 and CPB imaging system axis 42 include an angle GFE, and the CPB imaging system axis forms an angle GE with the normal to the wafer surface 55. In the coordinate system of FIG. 1, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam.

Generally, a FIB column 50 can for example be a Gallium FIB, with or without a Wien filter or similar mechanism to allow alloy-based sources (such as silicon, gold, etc.), or a FIB with a gas field ion source (GFIS), plasma source or duo-plasmatron with other kinds of ion species, such as Xenon, Oxygen or Argon ions or related technologies (for example “cluster” or “low temperature” ion sources). Generally, FIB column 50 is used to produce focused ion beams, optionally at different charge states of ions.

With the charged particle beam imaging system 40, inclined under angle GE to the wafer normal, images of the milled surfaces are acquired. In the example of FIG. 1, the angle GE is about 15°. However, other arrangements are possible as well, for example with GE=GF, such that the CPB imaging system axis 42 is perpendicular to the FIB axis 48 (and GFE=90°), or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer 8 at inspection site 6.1, and secondary particles as well as scattered particles are generated. For example, secondary electron particle detector 17.1 collects at least some of the secondary particles and scattered particles and communicates the particle count with a control unit 19. Other detectors for other of interaction products may be present as well, for example in-lens detector 17.2 for collection of backscattered charged particles. Control unit 19 is in control of the charged particle beam imaging column 40, of FIB column 50 and connected to a stage control unit 16 to control the position of the wafer 8 mounted on the wafer support table 15 via the wafer stage 155. Control unit 19 communicates with operation control unit 2, which triggers placement and alignment for example of inspection site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM). In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface 55.

The dual beam system 1 further comprises a gas injection system (GIS) 79, with a gas nozzle connected via a valve (not shown) to at least one gas reservoir (not shown). Thereby, controlled amounts of precursor gases can be provided during milling or imaging, and for example metal coatings can be generated. For example, alignment marks or fiducials can be generated. For example, a Tungsten metal coating is generated by providing Tungsten Hexacarbonyl. The metal coating can be shaped by ion beam milling and alignment markers or fiducials are formed in proximity to an inspection site. Thereby, a precise registration and image alignment of the plurality of cross section images is enabled. With dedicated precursor gases, a milling operation by FIB 51 can be enhanced. For example, a homogeneity of a milling operation in compositions of different material can be improved and curtaining can be reduced. Compositions of materials in a semiconductor wafer can comprise Silicon, Silicon Dioxide, Silicon Nitride, Copper, Aluminum, or other materials.

Examples precursor gases include comprising at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PMCPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, and combinations thereof.

Furthermore, dual beam system 1 further comprises a contact pin 81. Contact pin 81 is connected to a manipulator (not shown) for precise movement of the contact pin 81, for example under control of the charged particle beam 44 during an image acquisition. Thereby, structures present on the wafer surface can be contacted and electrically connected to control device 19.

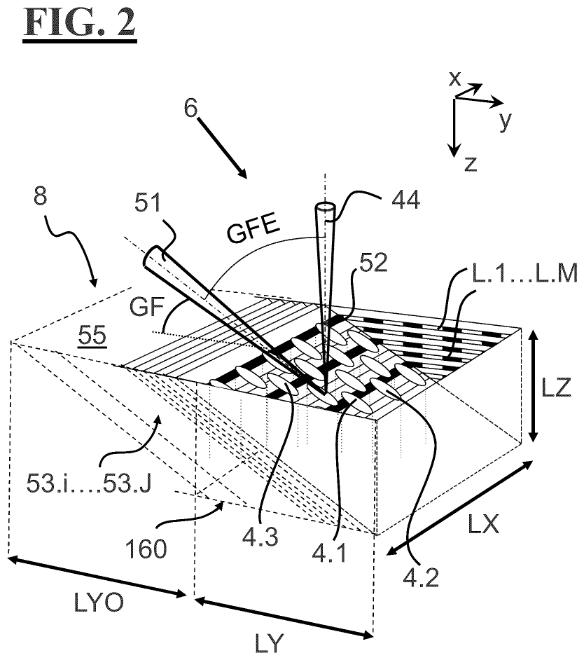

FIG. 2 illustrates the wedge cut geometry at the example of a 3D-memory stack. FIG. 2 illustrates the situation, when the surface 52 is the new cross-section surface which was milled last by FIB 51. The cross-section surface 52 is scanned for example by SEM beam 44, which is in the example of FIG. 2 arranged at normal incidence to the wafer surface 55, and a high-resolution cross-section image slice is generated. The cross-section surfaces 53.1 . . . 53.N are subsequently milled with a FIB beam 51 at an angle GF of approximately 30° to the wafer surface 55, but other angles GF, for example between GF=20° and GF=60° are possible as well. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . L.M, which comprise for example SiO2, SiN- or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44. During repeated milling and imaging, a plurality of cross sections is formed, and a plurality of cross section images are obtained, such that an inspection volume of size LX×LY×LZ is properly sampled and for example a 3D volume image can be generated. Thereby, the damage to the wafer is limited to the inspection volume 160 plus a damaged volume in y-direction of length LYO. With an inspection depth LZ about 10 μm, the additional extension of the damage volume in y-direction is typically limited to below 20 μm.

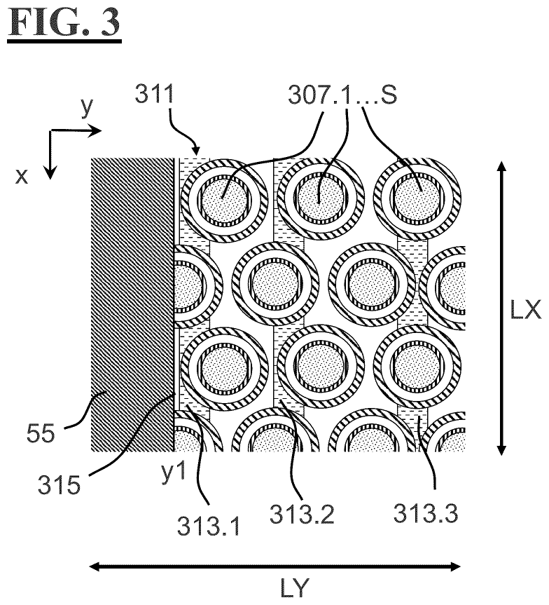

FIG. 3 shows an example of a cross-section image slice 311 generated by the imaging charged particle beam 44, corresponding to the cross-section surface 52. The cross-section image slice 311 comprises an edge line 315 between the slanted cross-section and the surface 55 of the wafer at the edge coordinate y1. Right to the edge, the image slice 311 shows several cross-sections 307.1 . . . 307.S through the HAR structures which are intersected by the cross-section surface 52. In addition, the image slice 311 comprises cross-sections of several word lines 313.1 to 313.3 at different depths or z-positions. With these word lines 313.1 to 313.3, a depth map Z₁(x, y) of the slanted cross-section surface 52 can be generated. Further, after performing a segmentation and annotation of a cross-section image of a semiconductor object of interest, HAR channel cross sections are identified and properties of HAR channel cross sections are determined by machine learning methods. Examples are described in WO 2022/223229A1 and PCT/EP2022/082590, which are hereby incorporated by reference

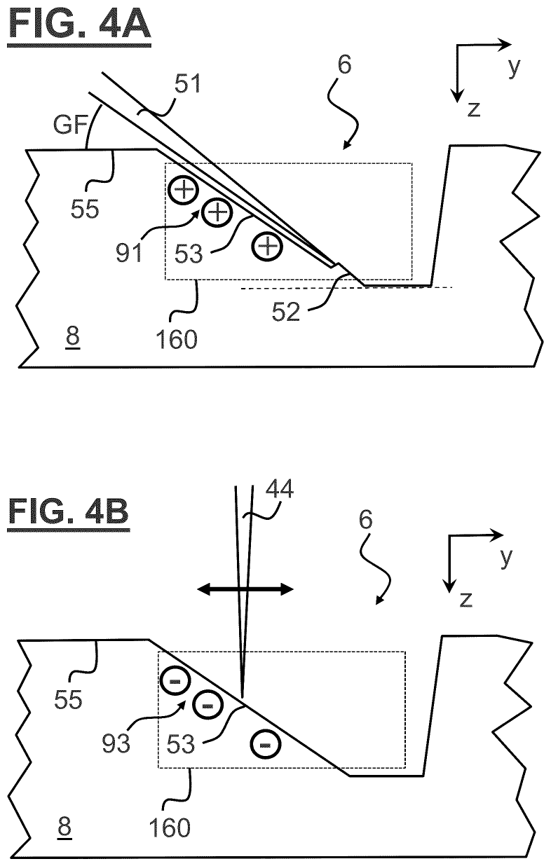

FIGS. 4A-4B illustrate examples of charging effects during milling and imaging. Same reference numbers as in FIGS. 2 and 3 are used, and reference is made to the description of FIGS. 2 and 3. Due to the exposure to charged particle beams, local surface charges may be generated. Wafers 8 are typically made of semiconductor materials such as Silicon, and may comprise locally isolated capacities, which may accumulate charge. Local charges may be generated at the surface or inside of isolators, such as SiO2 (silicon dioxide), and these local charges may stick to the surface or stay inside the insulator for a relatively long time. Local charges may also be accumulated within isolated conductors, which form capacities for collecting charge. Locally trapped charges typically only slowly decay due to for example thermal diffusion. These local charges may deflect or deteriorate the charged particle imaging beam 44, and for example generate a local distortion or a local focus offset or a may have an impact on a secondary or backscattered electron yield. Local charges may also deflect or deteriorate the ion beam 51 and cause a deflection of the ion beam 51 away from the cross-section surface 53 during milling. As an effect, a cross section surface 53 can have a curved shape. Local charges can be generated by charged particle imaging beam 44 as well as with ion beam 51. In both cases, positive as well as negative charging may be generated, depending on the kinetic energy and material composition of the sample.

FIG. 4A illustrates a milling step with ion beam 51 with positive charged ion species, for example Gallium, Argon, or Xenon Ions. During milling, the positive ions may rip off electrons from the newly formed cross section surface 53 and create a positive charge 91 at and below next cross section surface 53. FIG. 4B illustrates an imaging step with an electron beam 44. According to the kinetic landing energy of the primary electrons, less secondary electrons may be extracted from the cross-section surface 53 as primary electrons are impinging, thereby creatin a local negative charge 93 close to the surface 53.

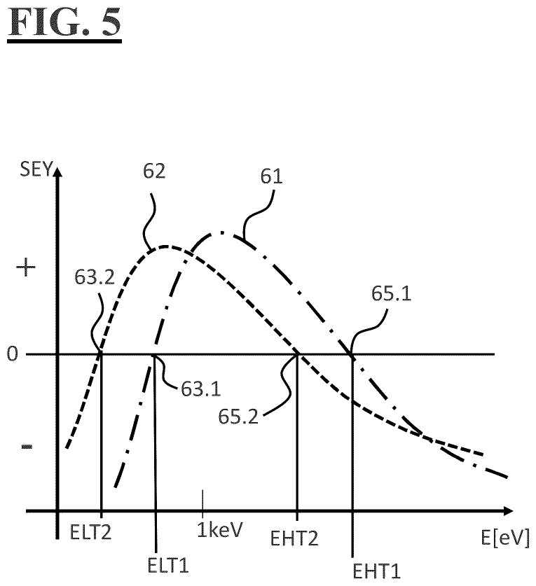

FIG. 5 illustrates a charging behavior of an electron beam imaging system. Typically, the charging of a surface or capacities depends on the material composition and the kinetic landing energy of the primary electrons. FIG. 5 shows the secondary electron yield (SEY) curve 61 for a first material composition and the SEY curve 62 for a second material composition. With kinetic landing energies between the balance points ELT and EHT, a positive charge is created. With a kinetic landing energy of for example between EHT2 and EHT1 according to the SEY-curves of the two material compositions, parts of a cross-section surface 53 may build up positive charge, while other parts will build up negative charge during scanning acquisition of a digital image of the cross-section surface 53. However, within a semiconductor wafer 8, only limited material compositions are present, for example a first material composition with secondary electron yield (SEY) curve 61 with a maximum value of high energy transition point EHT1 and a second material composition with secondary electron yield (SEY) curve 62 with a minimum value of low energy transition point ELT2.

According to a first embodiment of the disclosure, a method of milling and image acquisition of a plurality of cross section surfaces with reduced impact of charging effects is provided. According to the method, a sequence of milling and image acquisition of a plurality of cross section surfaces comprises the steps of
generating by ion-beam milling, into an inspection volume of a wafer 8, a cross-section surface 53, comprising generating a surface charge (91, see FIG. 4A) with the ion beam 51,
scanning, by an electron beam 44, at least segments of the cross-section surface 53 with primary electrons with a kinetic landing energy below a minimum low-energy transition energy ELT2 or above a maximum high energy transition energy EHT1 of the material compositions present in a sample (see FIG. 5), thereby compensating the surface charge generated during ion-beam milling by creating a compensating negative surface charge (93, see FIG. 4B).

In an example, ion-beam milling and a first electron-beam scanning is performed in parallel. Electron beam current, scanning frequency and kinetic landing energy of the first electron-beam scanning can be adjusted to reduce the surface charge generated during ion-beam milling below a predefined threshold, such that a deflection angle of the ion beam 51 induced by the surface charge during milling is below 70mrad or less, for example below 30 mrad, below 10 mrad even below 1 mrad.

In an example, ion-beam milling and an electron-beam scanning is performed sequentially. During a first electron-beam scanning, the positive surface charge 91 is reduced. An image acquisition is performed during a second electron-beam scanning. Thereby, electron beam 44 is not influence by any surface charge 91 generated during milling. First and second electron-beam scanning can be performed with first and second parameters of the electron beam scanning operation, wherein the parameters comprise at least one of a kinetic landing energy, a scanning frequency and an electron beam current.

With the method according to the first embodiment, a surface bending of cross-section surfaces 53 is minimized. With the method according to the first embodiment, high quality electron beam images can be obtained, with reduced impact of surface charges 91 generated during ion beam milling.

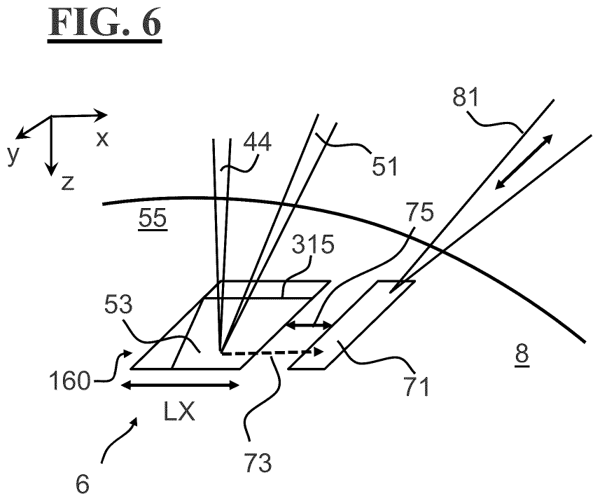

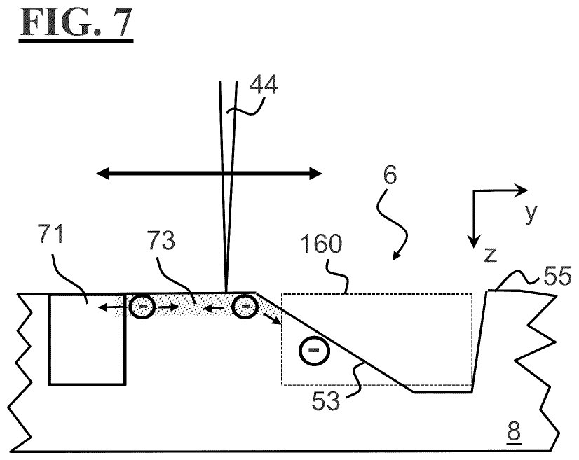

According to a second embodiment of the disclosure, a method of image acquisition with reduced impact of charging effects is provided. An example of the method according to the second embodiment is illustrated in FIG. 6. FIG. 6 shows an inspection site 6.1 on a surface 55 of a wafer 8. A cross-section surface 53 is milled by ion beam 51 and imaged by electron beam 44. The cross-section surface 53 forms an edge 315 with the wafer surface 55. Generally, the wafer surface 55 as well as the cross-section surface is an insulator or comprises large areas of insulating material compositions, such as pure Silicon or Silicon Dioxide. According to the method, a large capacity 71 is generated adjacent to the inspection site 6.1. The capacity 71 can for example be generated by a coating deposition of a metal layer. Capacity 71 may also be present as a large capacity within the structured wafer, for example formed by a large metal interconnection line or similar. During milling or image acquisition, charged particle beam 44 is swept from cross-section surface 53 to the capacity 71. With exposure with charged particle imaging beam 44, the wafer surface 55 becomes conducting and charges generated or accumulated on or below surface 53 are guided to capacity 71. With exposure with charged particle imaging beam 44, a temporary guiding connection 73 is formed. Thereby, a surface charge 91 or 93 flows via temporary guiding connection or conducting zone 73 to capacity of charge dump 71. Thereby, a surface charge 91 or 93 is reduced. An example of the method is further illustrated in FIG. 7. During exposure with charged particle beam 44, a local conducting zone or guiding connection 73 is formed. The physical principle behind is the excitation of valence electrons in a semiconductor, being a band gap insulator. With kinetic energy of charged particles of the charged particle beam 44 exceeding the band gap of the order of 1 eV to 10 eV, electrons are kicked out of the valence band and thus hole conduction is possible. Thereby, by sweeping the charged particle beam 44 over the wafer surface 55 with kinetic landing energy above the band gap energy, a temporary guiding connection 73 is formed between cross section surface 53 and charge dump 71. Thereby, local charges 91 or 93 are flowing to charge dump 71. Charge dump 71 may be formed by a metal structure on top of the wafer surface 55 or formed by metal deposition in a trench. After a capacity limit of charge dump 71 is reached, charge dump 71 can be connected via contact pin 81 to a large capacity, for example an external capacity, for example ground level. In the example of FIG. 7, a charge dump 71 is generated by deposition of a certain volume amount of a conducting material, such as a metal. The volume can be previously milled into the wafer surface 55. A volume amount can also be provided as an additional layer on the wafer surface 55. In some examples, a large capacity may already be present in the vicinity of the inspection site 160, and the large capacity can serve as charge dump 71. Such a large capacity is for example formed by a grounding path or a voltage supply line within a semiconductor wafer 8.

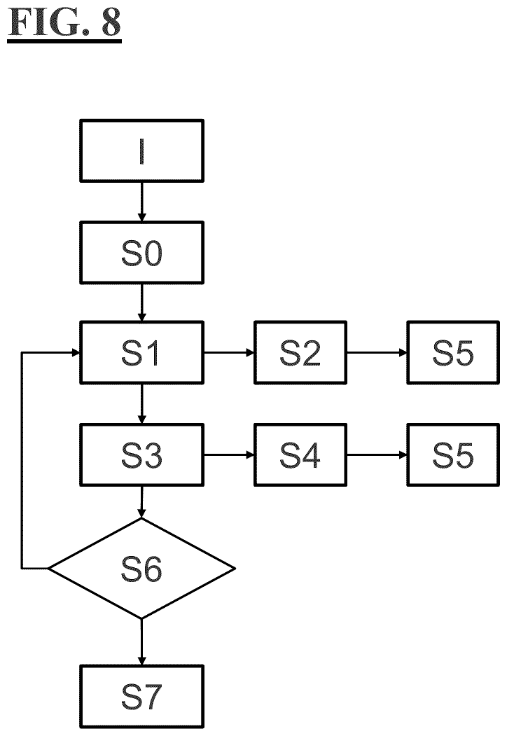

FIG. 8 illustrates and example of the method according to the second embodiment.

In Step I, an inspection site 6.i is adjusted by wafer stage 155 at the optical axis 42 of the charged particle imaging system 40 or the intersection point 43 of the dual beam device 1 and a process for slicing and imaging is determined and initialized. The process can include a local registration of coordinates at the inspection site and the generation of alignment fiducials.

During step S0, a capacity 71 is determined adjacent to the inspection volume 160. If no capacity 71 is present, capacity 71 is formed by deposition of a metal volume, for example formed by deposition of a Tungsten layer. In an example, capacity 71 is formed in a groove, which is first milled by ion beam 51 into the surface 55 of the wafer 8.

In step S1, a cross-section surface 53 is formed into the surface 55 of the wafer by ion-beam milling.

In step S2, electron beam 44 is scanned between the milling area of cross section surface 53 and the capacity 71 (see FIG. 7). Thereby, a local and temporally conducting zone 73 is generated, which enables a flow of charges between cross section surface 53 and capacity 71. Flowing charges can either be positively charged “holes” or negatively charged electrons. Thereby, surface charges generated during ion beam milling are reduced.

In Step S3, an image of the cross-section surface 53 is formed by imaging electron beam 44. During the imaging operation, electron beam 44 is scanned over the cross-section surface 53. At each scanning position, secondary electrons are emitted and collected by detectors 17.1 or 17.2 (see FIG. 1). Per each scan position, the signal corresponding to the collected secondary electrons depends for example on material composition or topography at the surface 25 of the wafer 8.

Generally, during step S3, a digital image of a segment of a surface (55) of the wafer 8 is formed. In an example, the cross-section surface 53 is equivalent to a segment of the surface 55 of the wafer 8.

In Step S4, electron beam 44 is scanned between the area of cross section surface 53 and the capacity 71 (see FIG. 7). Thereby, a local and temporally conducting zone 73 is generated, which enables a flow of charges between cross section surface 53 and capacity 71. Flowing charges can either be positively charged “holes” or negatively charged electrons. Thereby, surface charges generated during imaging with electron beam 44 are reduced. Step S4 can either be performed after completion of an image acquisition of the cross-section surface 53 or can be repeated several times during an image acquisition. For example, after each predefined sequence of for example 10 or 20 scanning lines, a discharge operation according to step S4 can be interlaced between consecutive sequences of scanning lines.

In optional Steps S5, probe 81 is connected to capacity 71 by actuators (not shown) and a physical contact is created. Thereby, accumulated charges in capacity 71 are connected to ground level and removed from capacity 71.

In Step S6, it is evaluated whether the number N of cross-sections is milled and imaged, depending on the inspection task. The number N of milling steps S1 and imaging steps S3 can comprise N=1, N=100 or N=1000 or more iterations.

In Step S7, the plurality of two-dimensional images of the plurality of N cross-sections is processed and an inspection result is determined. Image data processing can comprise at least one member of the group data processing methods including
image registration,
depth map determination,
distortion compensation, including magnification adjustment,
image processing methods, such as noise removal, contrast enhancement, image normalization, and thresholding,
three-dimensional volume image generation,
feature detection and feature extraction, for example including template matching or machine learning algorithms, for example object detectors.

Examples of Step S7 are explained in more detail in WO2021/083581 A1, WO2021/083551 A1, WO2022/223229 A1, WO2021/180600 A1, which are incorporated by reference. As a final result, for example a position of a target feature, an relative position of at least two target features, a dimension, a shape or an area of a target feature, a deviation from a target feature, an error, a statistical property of a plurality of target features is determined and provided to the user.

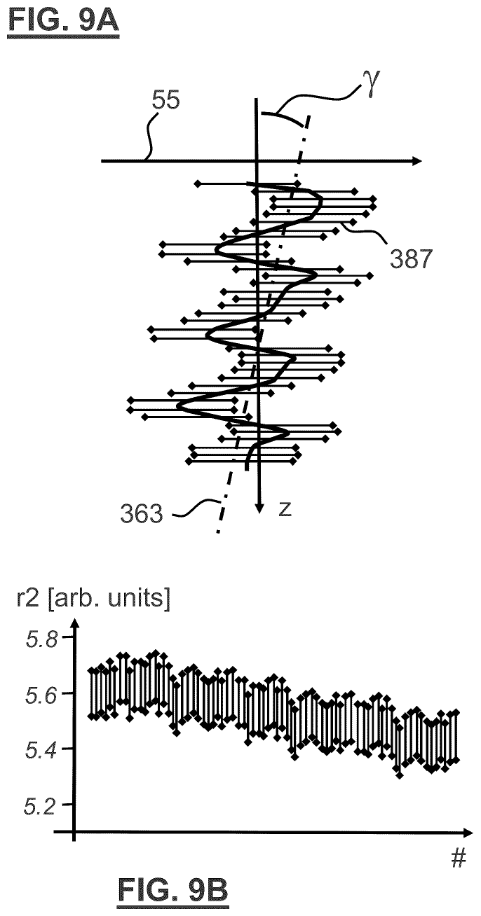

FIGS. 9A-9B show a result of step S7. In FIG. 9A, a trajectory of center coordinates of a HAR channel is shown. Each horizontal line corresponds to one contour of a feature 387, measured at a depth z inside an inspection volume of a wafer. Thereby, a HAR channel can be analyzed and for example an average tilt angle g of average channel trajectory 363 is determined. FIG. 9B illustrates a distribution of measured radius r2 of a plurality of wafer samples. The radius r2 shows a significant drift over wafer samples, which can be an indicator for a process drift during the manufacturing process of wafer.

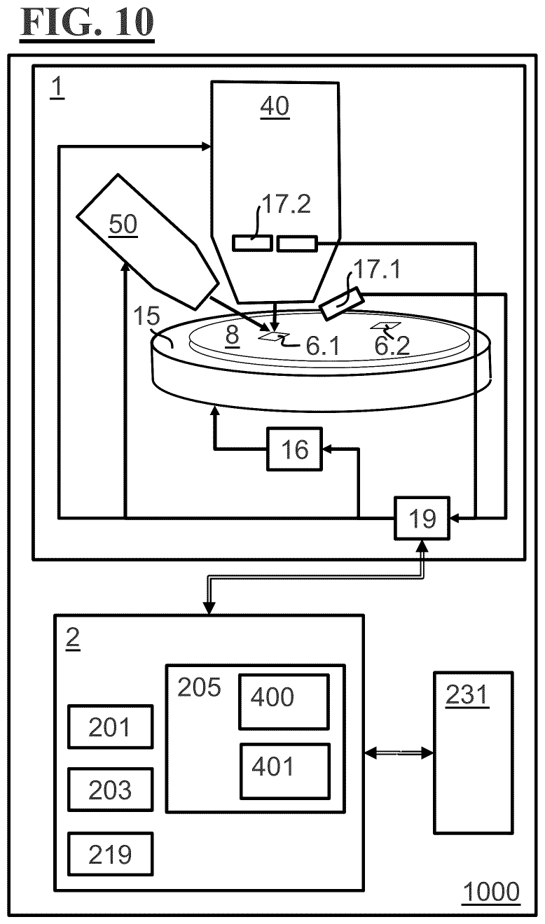

A wafer inspection system configured for executing a method according to the embodiments is further described in FIG. 10. The wafer inspection system 1000 comprises a dual beam system 1. A dual beam system is illustrated in FIG. 1 with more detail and reference is made to the description of FIG. 1. Certain features of a dual beam system 1 are a first charged particle or FIB column 50 for milling and a second, charged particle beam imaging system 40 for high-resolution imaging of cross section surfaces. A dual beam system 1 comprises at least one detector 17 for detecting secondary particles, which can be electrons or photons. A dual beam system 1 further comprises a wafer support table 15 configured for holding during use a wafer 8. The wafer support table 15 is position controlled by a stage control unit 16, which is connected to the control unit 19 of the dual beam system 1. The control unit 19 is configured with memory and logic to control operation of the dual beam system 1.

The wafer inspection system 1000 further comprises an operation control unit 2. The operation control unit 2 comprises at least one processing engine 201, which can be formed by multiple parallel processors including GPU processors and a common, unified memory. The operation control unit 2 further comprises an SSD memory or disk memory or storage 203 for storing data, for example including training data and a trained machine learning algorithm, and a plurality of cross-section images. The operation control unit 2 further comprises a user interface 205, comprising the user interface display 400 and user command devices 401, configured for receiving input from a user and display quotes or results to a user. The operation control unit 2 further comprises a memory or storage 219 for storing process information of the image generation process of the dual beam device 1 and for storing software instructions, which can be executed by the processing engine 201. The process information of the image generation process with the dual beam device 1 can for example include a library of the effects during the image generation and a list of predetermined material contrasts. The software instructions comprise software for performing a method according to the first or second embodiment.

The operation control unit 2 is further connected to an interface unit 231, which is configured to receive further commands or data, for example CAD data, from external devices or a network. The interface unit 231 is further configured to exchange information, for example receive instructions from external devices or provide measurement results to external devices or store a set of training data or a trained machine learning algorithm or plurality of cross section images in external storages.

The inspection system 1000 is configured to receive user information for execution of a method according to the embodiments, for example comprising CAD information of the semiconductor object of interest, the location of the inspection site, or the inspection result. The processing engine 201 is further configured to execute the method illustrated in FIG. 8 and described above. The processing engine 201 is configured to display information via the user display 400 and to receive user input via user interface 401.

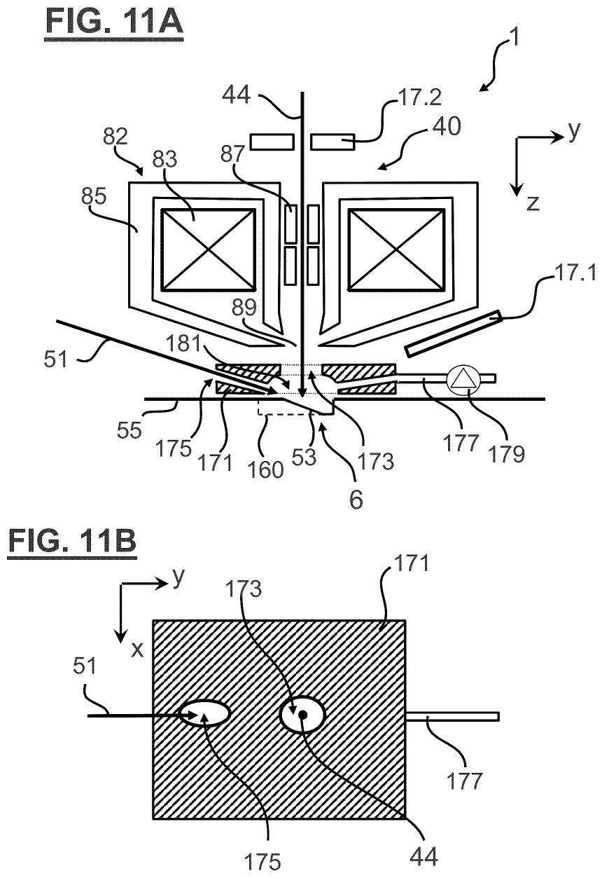

FIGS. 11A-11B illustrate a dual beam device 1 of wafer inspection system 1000 according to a third embodiment. FIG. 11A illustrates a cross-section of parts of a scanning electron beam device 40, configured for acquiring an image of cross section surface 53 inside of inspection volume 160. The two charged particle beams 44 and 51 of the dual beam system 1 are arranged in the y-z-plane. Cross-section surface 53 is generated by ion beam milling with ion beam 51, which forms with the electron beam 44 an angle GFE (see FIG. 1) between 55° and 90° in the y-z-plane. The scanning electron beam device 40 comprises a magnetic lens 82 with coil 83, a yoke 85, which forms a magnetic lens field in region indicated by reference number 89. In this example, the magnetic lens is a radial gap lens, wherein the gap of the yoke 85 is parallel to the electron beam axis (parallel to electron beam 44). Within the magnetic lens 82, at least two multi-pole elements 87 are arranged, configured to scanning deflect the electron beam 44. For example, the at least two multi-pole elements 87 are connected to a control unit (not shown), which is further configured to provide voltages or currents to the multi-pole elements 87, configured to correct aberrations of the electron beam 44, and for example to adjust a focus plane of the electron beam 44 according to the tilt angle GFE between cross-section plane 53, generated by ion beam 51 at angle GFE between 55° and 90° with respect to the electron beam.

Dual beam system 1 of the third embodiment further comprises a gas purging head 171 with a local gas purging volume 181, which can be positioned above the wafer surface 55 at the location of inspection site 160. The gas purging head 171 can for example be connected to an actuator for position adjustment and for forming a retraction system (not shown). Gas purging head 171 is connected to a gas supply 177 with a valve 179. Gas purging head 171 further comprises a first opening 173 for passing during use the scanning electron beam 44 and a second opening 175 for passing during use the ion beam 51. During use, the local gas purging volume 181 is encapsulated by the gas purging head 171 and the wafer surface 55. During use, a purging gas is provided through gas supply 177, controlled by a control device connected to valve 179. Thereby, a high gas pressure of a purging gas is generated in the local gas purging volume 181. By including for example an ionized gas or a combination of ionized gases provided by gas supply 177, local surface charges generated at cross-section surface 53 during milling or imaging are neutralized by ions of the ionized gas. Purging gases can be inert gases such a Nitrogen (N2), Xenon (Xe), Argon (Ar), Neon (Ne) or Helium (He). Thereby, a deterioration such as a deflection, a local distortion or a local focus offset during ion beam milling or charged particle beam imaging is reduced. Further details are disclosed in U.S. Pat. No. 8.552.406 B2, which is incorporated here within by reference. Examples of purging gases includes gases from the group of gases provided above, including Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PMCPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, and combinations thereof.

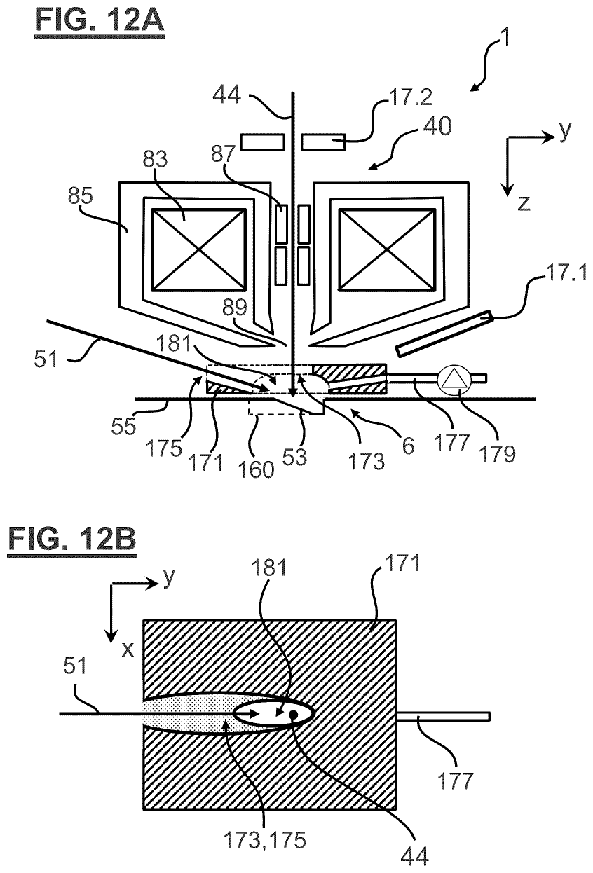

With the first and second beam passing openings 173 and 175, both particle beams 44 and 51 of a dual beam system 1 are enabled to enter and transmit the local gas purging volume 181. A cross section in x-y-plane is shown on FIG. 11B. FIGS. 12A-12B illustrate a further example according to the third embodiment. Same reference number are used as in FIG. 10, and reference is made to the description of FIGS. 11A-11B. In the example of FIGS. 12A-12B, first beam passing opening 173 and second beam passing opening 175 overlap and form a single beam passing opening of elongated shape in the y-direction, with narrower dimension I x-direction. With both examples, the opening size of the beam passing openings 173, 175 for passing the two charged particle beams is reduced and a high gas pressure of the purging gas for charge neutralization can be maintained during use within the local gas purging volume 181. Typical scanning areas of the charged particle beams 44 and 51 are about 10 μm. Typical opening sizes of the beam passing openings 173, 175 can be provided below 100 μm, for example below 80 μm, for example 50 μm. Thereby, scanning of charged particle beams over typical scanning areas is possible and a high purging gas pressure inside the local gas purging volume 181 is maintained.

With the method, the dual beam system and the wafer inspection system 1000 configured to execute a method according to the disclosure, a deterioration such as a deflection, a local distortion or a local focus offset during ion beam milling or charged particle beam imaging is reduced. The method and wafer inspection system 1000 can be used for quantitative metrology, but can also be used for defect detection, process monitoring, defect review, and inspection of integrated circuits within semiconductor wafers.

The disclosure can be described by following clauses:

Clause 1: A method of image acquisition, comprising:
image forming by scanning a charged particle imaging beam (44) over a segment of a surface (53,55) of a wafer (8) to form a two-dimensional image of the segment of the surface (53, 55);
generating a temporally conducting zone (73) between the segment of the surface (53, 55) and a capacity (71) by scanning the charged particle imaging beam (44) between the segment of the surface (53,55) and the capacity (71) to enable a flow of charges from the segment of the surface (53,55) to the capacity (71).

Clause 2: The method of clause 1, comprising:
ion-beam milling a segment of a surface (53, 55) of a wafer (8) with an ion beam (51), wherein the ion beam (51) is arranged at an angle GFE to the charged particle imaging beam (44).

Clause 3: The method of clause 2, wherein the step of generating a temporally conducting zone (73) by scanning the charged particle imaging beam (44) is performed during the ion-beam milling-step.

Clause 4: The method of any of the clauses 1 to 3, wherein the step of generating a temporally conducting zone (73) by scanning the charged particle imaging beam (44) is performed during the step of image forming.

Clause 5: The method of any of the clauses 1 to 4, further comprising, prior to generating a temporally conducting zone (73) between the segment of the surface (53, 55) and the capacity (71) by scanning the charged particle imaging beam (44), adjusting a kinetic energy of the charged particle imaging beam (44).

Clause 6: The method of any of the clauses 2 to 5, comprising, during performing the step of milling, a step of compensating a milling-induced charging by scanning the charged particle imaging beam (44) over a segment of the cross-section surface (53) during ion beam milling.

Clause 7: The method of clause 6, further comprising, prior to compensating a milling-induced charging by scanning the charged particle imaging beam (44), adjusting a kinetic energy of the charged particle imaging beam (44).

Clause 8: The method of any of the clauses 2 to 7, comprising repeating the steps of image forming, generating a temporally conducting zone (73), ion-beam milling and compensating a milling-induced charging to acquire a plurality of two-dimensional images of a plurality of cross-section surfaces (53) with reduced impact of a charging during ion-beam milling or image forming.

Clause 9: The method of any of the clauses 1 to 8, comprising:
determining the capacity (71) adjacent to the segment of the surface (53,55) of the wafer (8).

Clause 10: The method of clause 9, wherein the step of determining the capacity (71) comprises forming the capacity (71) adjacent to the segment of the surface (53,55) by deposition of a metal volume onto the surface (53, 55).

Clause 11: The method of any of the clauses 1 to 10, further comprising:
physically connecting a probe (81) with the capacity (71) to remove accumulated charges from the capacity (71).

Clause 12: The method of any of the clauses 1 to 11, further comprising
arranging a purge head (171) above the surface (55) of the wafer (8)
providing by a gas supply (177) a purging gas to the purge head (171) to form a local gas purging volume (181).

Clause 13: The method of clause 12, comprising selecting and providing the purging gas configured for neutralizing surface charges generated during image formation or ion-beam milling.

Clause 14: The method of clause 13, wherein the purging gas is selected from a group of gases including Nitrogen (N2), Xenon (Xe), Argon (Ar), Neon(Ne) or Helium (He).

Clause 15: The method of any of the clauses 1 to 14, further comprising an image processing of the two-dimensional image or images comprising image processing operations selected from the group of operations including image registration, depth map determination, distortion compensation, magnification adjustment, noise removal, contrast enhancement, image normalization, and thresholding, three-dimensional volume image generation, feature detection, feature extraction, template matching or machine learning object detectors.

Clause 16: The method of any of the clauses 1 to 15, further comprising adjusting a first inspection site (6.1) of a wafer (8) at the optical axis (42) of the charged particle imaging system (40).

Clause 17: A method of ion-beam milling a cross-section surface (53) into a wafer (8) with an ion beam (51), comprising, during performing the ion-beam milling, a step of compensating a milling-induced charging by scanning a charged particle imaging beam (44) over a segment of the cross-section surface (53) during ion-beam milling.

Clause 18: The method of clause 17, further comprising, adjusting a kinetic energy of the charged particle imaging beam (44) to reduce a surface charge generated during ion-beam milling.

Clause 19: The method of clause 18, comprising adjusting the kinetic energy below a minimum low-energy transition energy ELT2 or above a maximum high energy transition energy EHT1 of material compositions present at an inspection site (6.i) of the wafer (8).

Clause 20: The method of any of the clauses 17 to 19, further comprising
generating a temporally conducting zone (73) between the cross-section surface (53) and a capacity (71) by scanning the charged particle imaging beam (44) between the cross section-surface (53,55) and the capacity (71) to enable a flow of charges from the cross-section surface (53) to the capacity (71).

Clause 21: The method of clause 20, wherein the step of generating a temporally conducting zone (73) by scanning the charged particle imaging beam (44) is performed during the ion-beam milling.

Clause 22: The method clauses 20 or 21, further comprising, prior to generating a temporally conducting zone (73) between the cross-section surface (53) and the capacity (71) by scanning the charged particle imaging beam (44), adjusting a kinetic energy of the charged particle imaging beam (44).

Clause 23: The method of any of the clauses 17 to 22, comprising:
determining the capacity (71) adjacent to the segment of the cross-section surface (53).

Clause 24: The method of clause 23, wherein the step of determining the capacity (71) comprises forming the capacity (71) adjacent to the cross-section surface (53) by deposition of a metal volume onto the surface (55) of the wafer (8) and adjacent to the cross-section surface (53).

Clause 25: The method of any of the clauses 17 to 24, further comprising:
physically connecting a probe (81) with the capacity (71) to remove accumulated charges from the capacity (71).

Clause 26: The method of any of the clauses 17 to 25, further comprising
arranging a purge head (171) above the surface (55) of the wafer (8)
providing by a gas supply (177) a purging gas to the purge head (171) to form a local gas purging volume (181).

Clause 27: The method of clause 26, comprising selecting and providing the purging gas configured for neutralizing surface charges generated during ion-beam milling.

Clause 28: The method of clause 27, wherein the purging gas is selected from a group of gases including Nitrogen (N2), Xenon (Xe), Argon (Ar), Neon(Ne) or Helium (He).

Clause 29: The method of any of the clauses 17 to 28, further comprising
image forming by scanning the charged particle imaging beam (44) over the cross-section surface (53) of a wafer (8) to form a two-dimensional image of the cross-section surface (53).

Clause 30: The method of clause 29, wherein the step of generating a temporally conducting zone (73) by scanning the charged particle imaging beam (44) is performed during the step of image forming.

Clause 31: The method of any of the clauses 17 to 30, comprising repeating the steps of image forming, generating a temporally conducting zone (73), ion-beam milling and compensating a milling-induced charging to acquire a plurality of two-dimensional images of a plurality of cross-section surfaces (53) with reduced impact of a charging during ion-beam milling or image forming.

Clause 32: The method of clause 31, further comprising an image processing of the two-dimensional image or images comprising image processing operations selected from the group of operations including image registration, depth map determination, distortion compensation, magnification adjustment, noise removal, contrast enhancement, image normalization, and thresholding, three-dimensional volume image generation, feature detection, feature extraction, template matching or machine learning object detectors.

Clause 33: The method of any of the clauses 17 to 32, further comprising adjusting a first inspection site (6.1) of a wafer (8) at the optical axis (42) of the charged particle imaging system (40).

Clause 34: A method of operating a dual-beam system (1), comprising:
arranging a gas purging head (171) at an inspection site (6) adjacent to a surface (55) of a wafer (8),
providing via a gas supply (177) a purging gas to the gas purging head (171) to form a local gas purging volume (181),
guiding a charged particle imaging beam (44) through a first beam passing opening (173) of the gas purging head (171),
guiding an ion-beam (51) through a second beam passing opening (175) of the gas purging head (171),
ion-beam milling of a plurality of cross-section surfaces (53) at the inspection site (6) into the surface (55) of the wafer (8) with the ion beam (51),
image forming of a plurality of two-dimensional images of the cross-section surfaces (53) by scanning the charged particle imaging beam (44) over each cross-section surface (53).

Clause 35: The method of clause 34, comprising selecting and providing the purging gas configured for neutralizing surface charges generated during ion-beam milling or charged particle image forming.

Clause 36: The method of clause 35, wherein the purging gas is selected from a group of gases including Nitrogen (N2), Xenon (Xe), Argon (Ar), Neon(Ne) or Helium (He).

Clause 37: The method of any of the clauses 34 to 36, further comprising adjusting the inspection site (6) of the wafer (8) at the optical axis (42) of the charged particle imaging system (40).

Clause 38: A dual beam system (1) comprising
a charged particle imaging system (40);
an ion beam system (50);
a sample stage (155) with a wafer support table (15);
a control unit (2, 19) comprising a memory (219), the memory (219) storing a set of instructions and a processing engine (201) configured to execute the set of instructions to cause the dual beam system (1) to perform any of the methods of clauses 1 to 37.

Clause 39: The dual beam system (1) of clause 38, wherein the ion beam system (50) is generating a focused ion beam (51) comprising ions selected from a group including Gallium ions, Xenon ions, Oxygen ions, Neon ions, Argon ions, and Helium ions.

Clause 40: The dual beam system (1) of clause 38 or 39, wherein an optical axis (48) of the ion beam system (50) is arranged at an angle GFE to the optical axis (42) of the charged particle imaging beam system (40), and wherein the angle GFE is between 30° and 80°.

Clause 41: A wafer inspection system (1000) comprising the dual beam system of any of the clauses 38 to 40.

Clause 42: A dual beam system (1) comprising
a charged particle imaging system (40),
an ion beam system (50),
a sample stage (155) with a wafer support table (15),
a gas purging head (171) arranged between the charged particle imaging system (40), the ion beam system (50), and a surface (55) of a wafer (8),

wherein the gas purging head (171) comprises
a first beam passing opening (173) for guiding a charged particle imaging beam (44) through the gas purging head (171),
a second beam passing opening (175) for guiding an ion beam (51) through the gas purging head (171),

and wherein the gas purging head (171) is connected to a gas supply (177) for providing during use a purging gas to the gas purging head (171) to form a local gas purging volume (181).

Clause 43: The dual beam system (1) of clause 42, wherein the gas supply (177) is configured to provide a purging gas selected from a group of gases including Nitrogen (N2), Xenon (Xe), Argon (Ar), Neon(Ne) or Helium (He).

Clause 44: The dual beam system (1) of clause 42 or 43, wherein the first beam passing opening (173) and the second beam passing opening (175) are spatially separated and arranged at an angle corresponding to an angle GFE between the ion beam system (50) and the charged particle imaging system (40).

Clause 45: The dual beam system (1) of any of the clauses 42 or 44, wherein the gas purging head (171) is retractably mounted on an actuated mount.

Clause 46: The dual beam system (1) of any of the clauses 42 or 45, wherein the ion beam system (50) is generating a focused ion beam (51) comprising ions selected from a group including Gallium ions, Xenon ions, Oxygen ions, Neon ions, Argon ions, and Helium ions.

Clause 47: The dual beam system (1) of any of the clauses 42 or 46, further comprising a control unit (2, 19) comprising a memory (219), the memory (219) storing a set of instructions and a processing engine (201) configured to execute the set of instructions to cause the dual beam system (1) to perform any of the methods of clauses 1 to 37.

The disclosure described by examples and embodiments is however not limited to the clauses but can be implemented by those skilled in the art by various combinations or modifications.

### A LIST OF REFERENCE NUMBERS IS PROVIDED

1 Dual Beam system
2 Operation Control Unit
4 cross section image features
6 inspection sites
8 wafer
15 wafer support table
16 stage control unit
17 Electron detector
19 Control Unit
40 charged particle beam (CPB) imaging system
42 Optical Axis of imaging system
43 Intersection point
44 Imaging charged particle beam
48 Fib Optical Axis
50 FIB column
51 focused ion beam
52 cross section surface
53 cross section surface
55 wafer top surface
61 first SEY over kinetic energy
62 Second SEY over kinetic energy
63 low energy balance point
65 high energy balance point
71 charge dump
73 temporary guiding connection
75 gap
79 gas injection nozzle
81 contact pin
82 magnetic lens
83 coil
85 yoke
87 multi-pole elements
89 magnetic lens field
91 positive charge
93 negative charge
155 wafer stage
160 inspection volume
171 purge head
173 first beam passing opening
175 second beam passing opening
177 Gas supply
179 valve
181 local gas purging volume
201 processing engine
203 memory
205 User interface
219 memory
231 Interface unit
307 measured cross section image of HAR structure
309 image segment
311 cross section image slice
313 word lines
315 edge with surface
317 ring zone of HAR structure
318 noise
320 partially merged outer contour
321 center position
325 defect or deviation
327 pixelwise annotated rings
363 average HAR channel trajectory
379 contour gap
381 initial contour proposal
383 contour line of first feature
385 second contour proposal
387 contour of a feature
391 scaling vector
400 user interface display
401 user command devices
1000 Wafer inspection system

1. A method, comprising:
during ion-beam milling a cross-section surface into a wafer with an ion beam, compensating a milling-induced charging by scanning a charged particle imaging beam over a segment of the cross-section surface; and
adjusting a kinetic energy of the charged particle imaging beam to reduce a surface charge generated during ion-beam milling.

2. The method of claim 1, comprising adjusting the kinetic energy of the charged particle imaging beam to be:
i) below a minimum low-energy transition energy of material compositions present at an inspection site of the wafer; or
ii) above a maximum high energy transition energy of the material compositions present at the inspection site of the wafer.

3. The method of claim 1, further comprising generating a temporally conducting zone between the cross-section surface and a capacity by scanning the charged particle imaging beam between the cross section-surface and the capacity to flow of charges from the cross-section surface to the capacity via the temporally conducting zone.

4. The method of claim 3, wherein generating the temporally conducting zone is performed during ion-beam milling.

5. The method of claim 3, further comprising determining the capacity.

6. The method of claim 3, further comprising forming the capacity by depositing a metal volume onto a surface of the wafer at a location that is adjacent the cross-section surface.

7. The method of claim 3, further comprising connecting a probe with the capacity to remove accumulated charges from the capacity.

8. The method of claim 3, further comprising, simultaneously with generating the temporally conducting zone, forming a two-dimensional image by scanning the charged particle imaging beam over the cross-section surface of the wafer.

9. The method of claim 8, comprising repeating two-dimensional image formation, generating the temporally conducting zone, ion-beam milling and compensating the milling-induced charging, thereby acquiring a plurality of two-dimensional images of a plurality of cross-section surfaces.

10. One or more machine-readable hardware storage devices comprising instructions that are executable by one or more processing devices to perform operations comprising the method of claim 1.

11. A system comprising:
one or more processing devices; and
one or more machine-readable hardware storage devices comprising instructions that are executable by the one or more processing devices to perform operations comprising the method of claim 1.

12. A method, comprising:
providing a purging gas to a gas purging head disposed at an inspection site adjacent to a surface of a wafer, thereby forming a local gas purging volume;
passing a charged particle imaging beam through a first opening of the gas purging head;
passing an ion-beam through a second opening of the gas purging head;
ion-beam milling a plurality of cross-section surfaces at the inspection site into the surface of the wafer with the ion beam; and
forming a two-dimensional image of each of the cross-section surfaces by scanning the charged particle imaging beam over each cross-section surface.

13. The method of claim 12, comprising selecting and providing the purging gas to neutralize charges generated during ion-beam milling or two-dimensional image formation.

14. The method of claim 13, wherein the purging gas comprises at least one member selected from the group consisting of hydrogen, nitrogen, xenon, argon, neon, and helium.

15. The method of claim 12, further comprising adjusting the inspection site of the wafer at an optical axis of the charged particle imaging system.

16. A dual beam system, comprising:
a charged particle imaging system configured to provide a charged particle imaging beam;
an ion beam system configured to provide an ion beam; and
a control unit configured to:
i) during ion-beam milling a cross-section surface into a wafer with the ion beam, compensate a milling-induced surface charge by scanning the charged particle imaging beam over a segment of the cross-section surface; and
ii) adjust a kinetic energy of the charged particle imaging beam to reduce the milling-induced surface charge generated during ion-beam milling.

17. The dual beam system of claim 16, wherein an optical axis of the ion beam system is at an angle of between 30° and 80° relative to an optical axis of the charged particle imaging beam system.

18. The dual beam system of claim 16, further comprising a sample stage which comprises a wafer support table, wherein the dual beam system is a wafer inspection system.

19. The dual beam system of claim 16, the ion beam system is configured to generate a focused ion beam comprising ions selected from the group consisting of gallium ions, xenon ions, oxygen ions, neon ions, argon ions, and helium ions.

20. A dual beam system, comprising:
a charged particle imaging system configured to generate charged particle imaging beam;
an ion beam system configured to generate an ion beam;
a gas purging head between the charged particle imaging system, the ion beam system, and a surface of a sample within the dual beam system,
wherein the gas purging head comprises:
a first opening configured to have the charged particle imaging beam generated pass therethrough; and
a second opening configured to have the ion beam pass therethrough.

21.-27. (canceled)
